(19) United States
(12) Patent Application Publication
(10) Pub. No.: US 2005/0134405 A1
(43) Pub. Date: Jun. 23, 2005

(54) Electronic device and semiconductor device

(76) Inventors: Kentaro Ochi, Hitachi (JP); Akira Mishima, Mito (JP); Hitoshi Akamine, Maebashi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/999,953

(22) Filed: Dec. 1, 2004

(30) Foreign Application Priority Data
Dec. 1, 2003 (JP) 2003-401369

(51) Int. Cl. H03H 7/01

(52) U.S. Cl. 333/185

(57) ABSTRACT

This invention improves electric characteristics of electronic devices and semiconductor devices.

An electronic device comprising an inductive conductor section 4 forming a coil pattern 3 on each of three primary dielectric substrates 1a which are laminated into a multi-layer part, a capacitive conductor section 6 forming a capacitance pattern 5 on each of two secondary dielectric substrates 1b which are laminated into another multi-layer part, and external connection terminals 9 which are connected to both ends of the inductive conductor section 4 and the capacitive conductor section 6 by means of through-hole wiring 8; wherein the conductor sections 4 and 6 are laminated, each of the capacitive conductor sections 6 forming a capacitance pattern 5 has a slit 10 to shut off a flow of an eddy current from the coil pattern 3 to the conductor section 6, and this configuration can suppress a loss of eddy current and reduction in the Q factor and inductance (L) of the inductive conductor section 4.

### CLAIM OF PRIORITY

The present application claims priority from Japanese application serial no. 2003-401369, filed on Dec. 1, 2003, the content of which is hereby incorporated by reference into this application.

### FIELD OF THE INVENTION

This invention relates to an electronic device and a semiconductor device, and more particularly to a technology which is effective to improve electric characteristics of an electronic device made by laminating a plurality of dielectric substrates and a semiconductor device having thereof.

### BACKGROUND OF THE INVENTION

A conventional multilayer LC filter contains an inductance (L) and a capacitance (C) in a multilayer substrate member made of a plurality of dielectric substrates. The multilayer LC filter provides a plate-shaped capacitor layer under a spiral coil layer having a preset number of windings in a plurality of dielectric substrates. In this configuration, the conductor section and the capacitor section are vertically laminated. (For example, see Japanese Patent Laid-open No. 2002-217667)

### SUMMARY OF THE INVENTION

In the conventional multilayer LC filter (electronic device), the magnetic flux which generates in the inductive conductor section is absorbed by the capacitive conductor section. This causes an eddy current loss in capacitive conductors, reduces the quality factors (Q factor) of inductors, and finally reduces inductances (L).

Therefore, so many coil patterns must be laminated to get a desired inductance (L). This makes the multi-layer substrate thicker.

Further, the coil pattern must be wider to have a desired inductance (L). This makes the multi-layer substrate wider.

Such a multi-layered LC unit is used as a high-frequency resonance circuit for a filter or the like. The high-frequency resonance circuit has such a problem that the damping characteristic of the resonance circuit deteriorates as the Q factor of the inductor (L) or capacitor (C) goes low.

It is an object of this invention to provide electronic devices and semiconductor devices whose electric characteristics can be improved.

It is another object of this invention to provide electronic devices and semiconductor devices that can be downsized.

The above and other objects, features and advantages of the present invention will become more apparent from the following description with reference to the accompanying drawings.

Representative features disclosed by this invention will be outlined below.

This invention relates to an electronic device made of multi-layered dielectric substrates comprising

a plurality of primary dielectric substrates which respectively have a circular inductive conductor section and electrically connect these multi-layered circular inductive conductor sections and

a secondary dielectric substrate which is laminated with said primary dielectric substrate and has a plane conductor section on it; wherein

the laminated inductive conductor sections form a coil pattern whose ends are connected to external connection terminals.

said coil pattern is laminated with said plane conductor section, and

said plane conductor section has a slit.

This invention relates to an electronic devices containing inductive conductor sections of coil patterns in a multi-layered substrate comprising a plurality of dielectric substrates and capacitive conductor sections of capacitance patterns; wherein

external connection terminals are provided to connect said inductive conductor section and said capacitive conductor sections electrically at both ends of the terminals by means of through-holes,

the capacitive conductor sections of said capacitance pattern contains a slit, and

said inductive conductor sections and said capacitive conductor sections are laminated in a body.

This invention relates to a semiconductor device comprising

an electronic device which consists of a plurality of primary dielectric substrates which respectively have a circular inductive conductor section and electrically connect these multi-layered circular inductive conductor sections and a secondary dielectric substrate which is laminated with said primary dielectric substrate and has a plane conductor section on it, wherein said plane conductor section is laminated with the coil pattern formed by the laminated inductive conductor sections and said plane conductor section contains a slit,

a semiconductor chip which forms a semiconductor element,

a wiring substrate which electrically connects said electronic device and said semiconductor chip, and

a plurality of external terminals provided on said wiring substrate.

Representative features disclosed by this invention will be outlined below.

This invention can provide a resonance circuit, improve electric characteristics of electronic and semiconductor devices, and further downsize the devices.

### BRIEF DESCRIPTION OF THE DRAWINGS

FIG. 1 is a perspective view of a sample structure of an electronic device which is a first embodiment of this invention.

FIG. 2 is an exploded view of components of an example of the electronic device of FIG. 1.

FIG. 3 is a schematic circuit diagram showing an example of circuit. of the electronic device of FIG. 2.

FIG. 4 is a plan view showing an example of structure of an inductive conductor section formed on a dielectric substrate of the electronic device of FIG. 2.

FIG. 5 is a plan view showing an example of structure of a capacitive conductor section formed on a dielectric substrate of the electronic device of FIG. 2.

FIG. 6 is a vertical sectional view of an example of structure of the electronic device of FIG. 2.

FIG. 7 is a graph showing a sample relationship between Q factor and frequency of conductor sections on dielectric substrates of the electronic device of FIG. 2 in terms of thickness of the conductor section as a parameter.

FIG. 8 is a graph showing an example of relationship between Q factor and frequency of conductor sections on dielectric substrates of the electronic device of FIG. 2 in terms of width of the conductor section as a parameter.

FIG. 9 is an exploded view showing components of a variation of the electronic device of FIG. 1.

FIG. 10 shows an example of shape of a plane conductor on the dielectric substrate used for the electronic device of FIG. 1.

FIG. 11 shows a plane view of a variation of shape in the plane conductor section on a dielectric substrate for the electronic device of FIG. 1.

FIG. 12 shows a plane view of a variation of shape in the plane conductor section on a dielectric substrate for the electronic device of FIG. 1.

FIG. 13 shows a plane view of a variation of shape in the plane conductor section on a dielectric substrate for the electronic device of FIG. 1.

FIG. 14 shows a plane view of a variation of shape in the plane conductor section on a dielectric substrate for the electronic device of FIG. 1.

FIG. 15 shows a plane view of a variation of shape in the plane conductor section on a dielectric substrate for the electronic device of FIG. 1.

FIG. 16 is a cross-sectional view of a sample structure of a semiconductor device which is a second embodiment of this invention.

FIG. 17 is a schematic circuit diagram showing an example of circuit connection of a semiconductor device of FIG. 16.

FIG. 18 is a circuit block diagram showing an example of circuit configuration of a semiconductor device of FIG. 16.

### DETAILED DESCRIPTION OF THE INVENTION

Basically in the description of preferred embodiments below, the same or similar components will not be described repeatedly for simplicity unless otherwise required.

Further, the preferred embodiments will be divided into several sections or embodiments for explanation if necessary for the sake of convenience. However, they are not unrelated to each other unless otherwise described explicitly. One component is a partial or whole variation of the others, or detailed or supplemental explanation of the others.

Further in the description below, the numbers of elements and the like (number of pieces, values, quantities, and ranges) are not limited to those of the preferred embodiments and can be greater or smaller than them.

Below will be described preferred embodiments of the present invention with reference to the accompanying drawings. In all drawings for explanation of the preferred embodiment, like elements are given like reference characters.

(Embodiment 1)

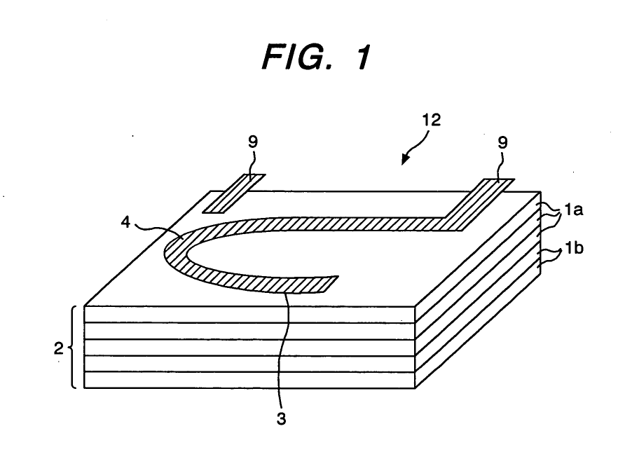

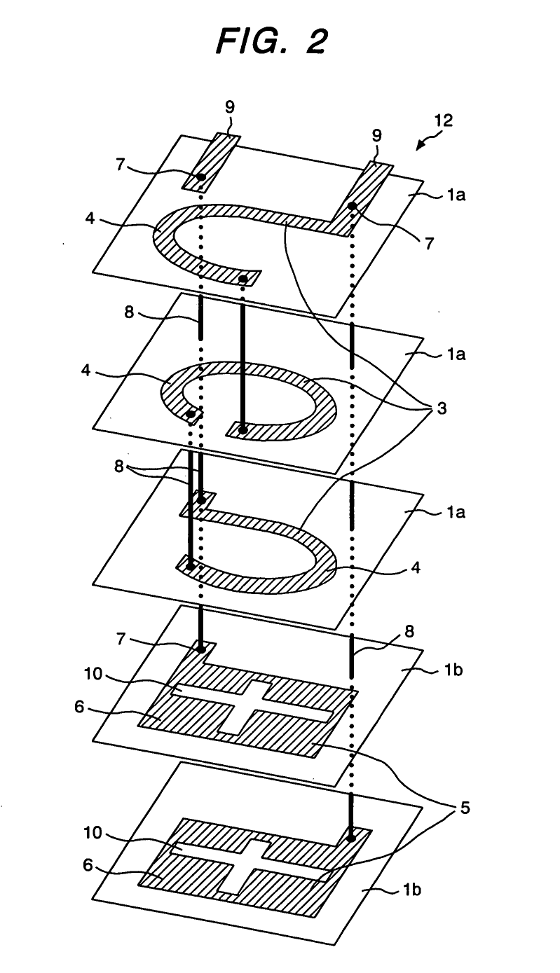

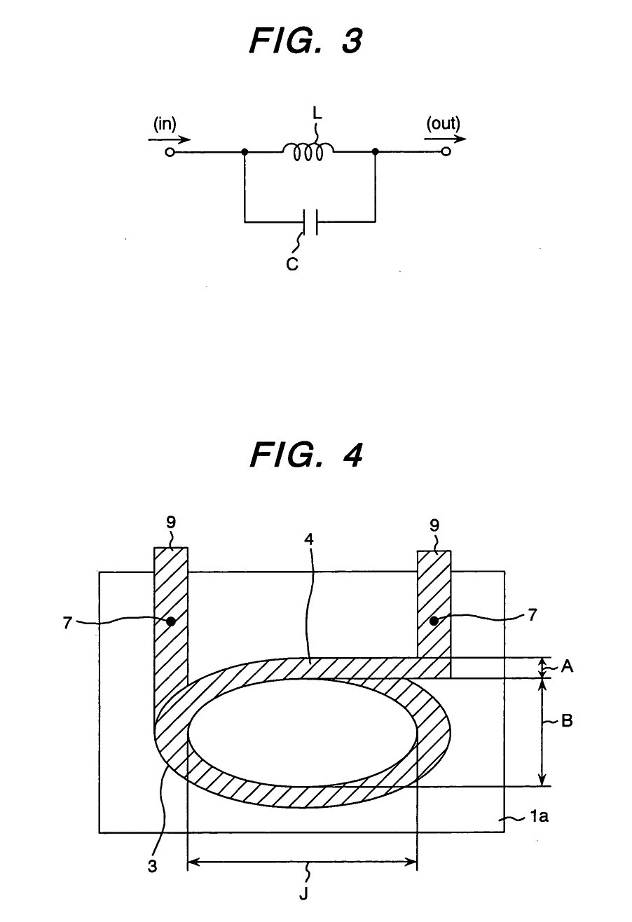

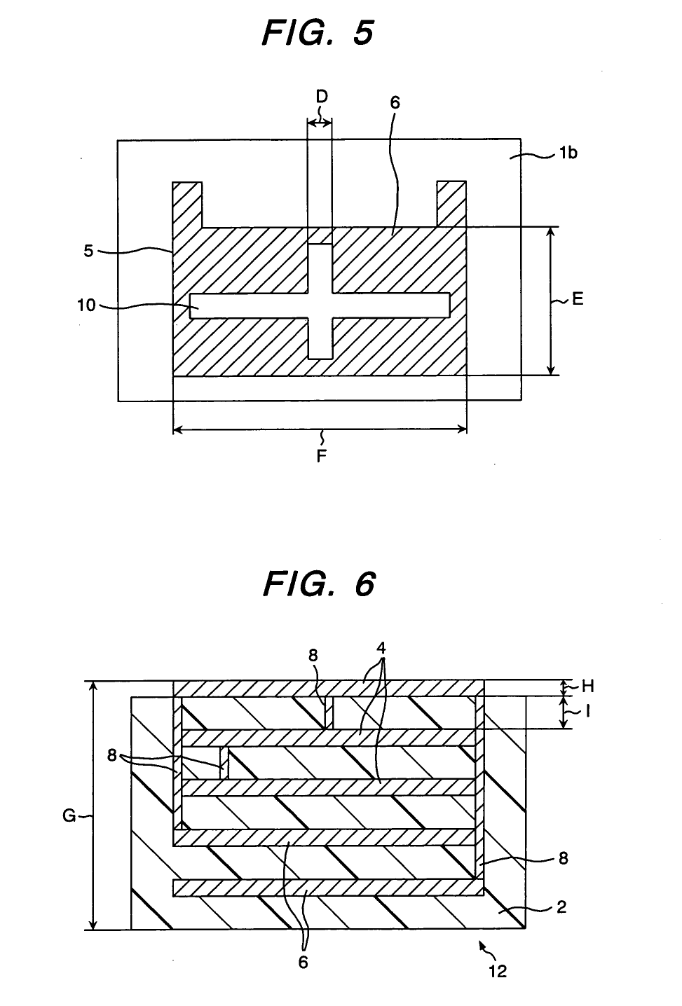

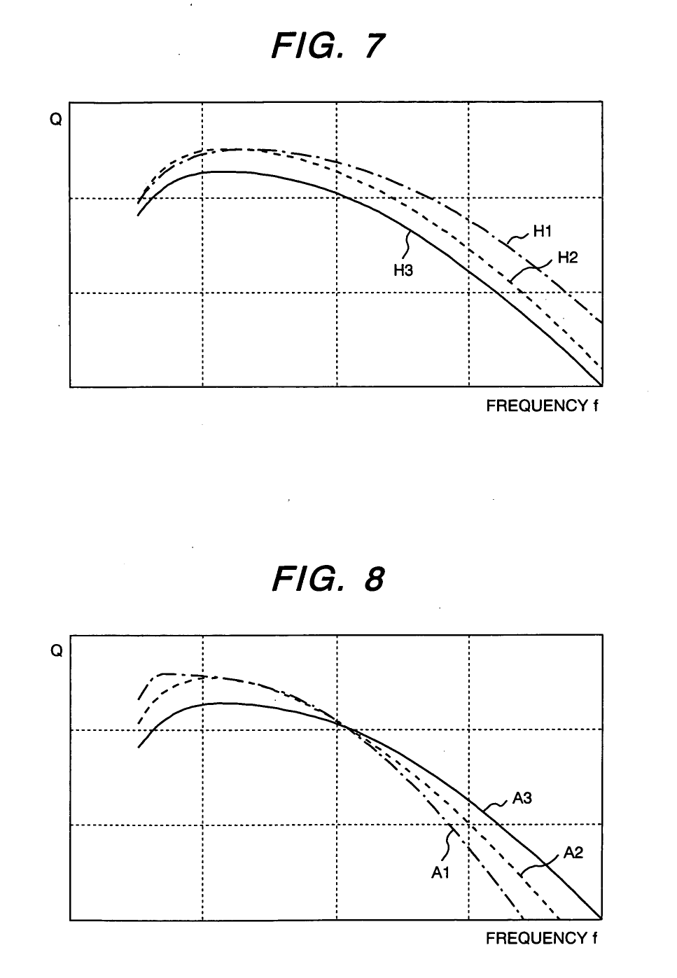

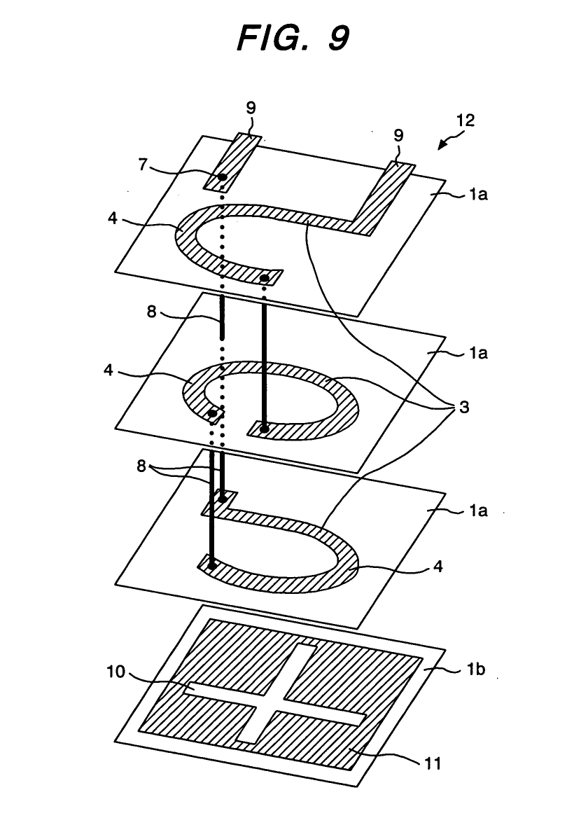

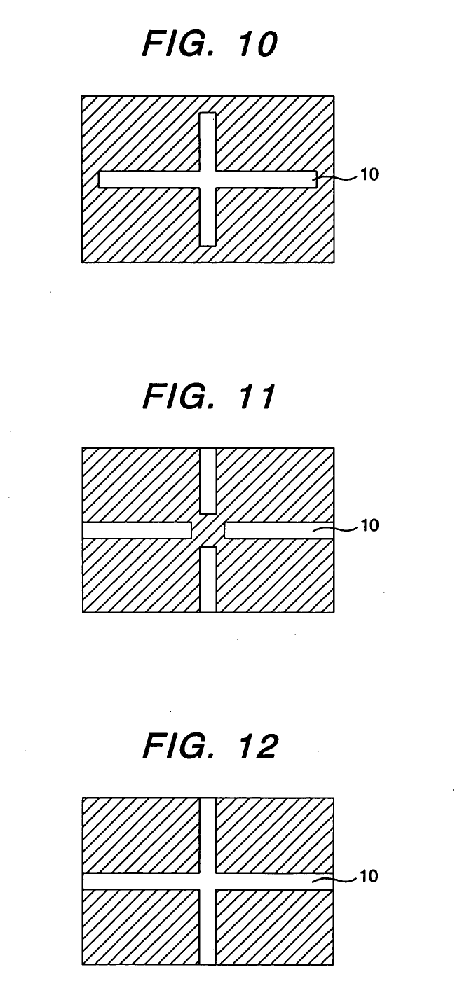

FIG. 1 is a perspective view of a sample structure of an electronic device which is a first embodiment of this invention. FIG. 2 is an exploded view. of components of the electronic device of FIG. 1. FIG. 3 is a schematic circuit diagram showing an example of circuit of the electronic device of FIG. 2. FIG. 4 is a plan view showing an example of structure of an inductive conductor section formed on a dielectric substrate of the electronic device of FIG. 2. FIG. 5 is a plan view showing an example of structure of a capacitive conductor section formed on a dielectric substrate of the electronic device of FIG. 2. FIG. 6 is a vertical sectional view of an example of structure of the electronic device of FIG. 2. FIG. 7 is a graph showing a sample relationship between Q factor and frequency of conductor sections on dielectric substrates of the electronic device of FIG. 2 in terms of thickness of the conductor section as a parameter. FIG. 8 is a graph showing an example of relationship between Q factor and frequency of conductor sections on dielectric substrates of the electronic device of FIG. 2 in terms of width of the conductor section as a parameter. FIG. 9 is an exploded view showing components of a variation of the electronic device of FIG. 1. FIG. 10 shows an example of shape of a plane conductor on the dielectric substrate used for the electronic device of FIG. 1. FIG. 11 to FIG. 15 respectively show variations of shapes of plane conductor sections of the dielectric substrates used for the electronic device of FIG. 1.

The electronic device of FIG. 1 which is the first embodiment of this invention is a multi-layer unit formed by laminating dielectric substrates of ceramic, glass, or the like and specifically it is a passive element part 12 having an inductive conductor section 4 for an inductance (L). The electronic device is a lamination of inductive conductor sections 4 and plane conductor sections which are solid conductor patterns (wiring patterns that are much wider than normal wiring pattern). It is, for example, a multi-layer LC filter.

The passive element part 12 of FIG. 2 is a kind of said electronic device whose plane conductor section is a capacitive conductor section 6 and forms a capacitance (L) by the capacitive conductor section 6.

The structure of the passive element part 12 of FIG. 2 is explained below in detail. The passive element part consists of an inductive conductor section 4 containing a coil pattern 3 in a multi-layer substrate unit 2 formed by laminating three primary dielectric substrates and a capacitive conductor section 6 having a capacitance pattern 5 in a multi-layer substrate unit 2 formed by laminating two secondary dielectric substrates 1b. Each of the inductive conductor section 4 and the capacitive conductor section 6 has external connection terminals 9 on both ends of the conductor section to electrically connect the conductor sections by means of through-hole wirings 8. Further, the inductive conductor section 4 and the capacitive conductor section 6 are laminated together. Furthermore, a slit 10 is formed on each of two opposite capacitors that constitute the capacitance patterns 5.

In other words, the passive element part 12 consists of a lamination of three primary dielectric substrates 1a each of which has an inductive conductor section 4 of a coil pattern 3 and two dielectric substrates 1b each of which has a capacitive conductor section 6 of a capacitance pattern 5. In short, a multi-layer substrate unit 2 laminating three primary dielectric substrates 1a and two dielectric substrates 1b contains the inductive conductor sections 4 having coil patterns 3 and the capacitive conductor section 6 having capacitance patterns 5. The conductor sections 4 and 6 are vertically laminated. Further, each of two capacitive conductor sections 6 forming capacitance patterns contains a slit 10.

Connection electrodes 7 are provided at both ends of the inductive conductor sections 4 and the capacitive conductor section 6 to electrically connect the-conductor sections to external connection terminals 9 by means of through-hole wirings 8.

The slit 10 of the capacitive conductor section 6 is cross-shaped with its center aligned. to the center of the coil pattern. In other words, the center of the cross-shaped slit 10 of the capacitive conductor section 6 is put in the center of the coil pattern 3 of the inductive conductor section 4.

Further, the areas of the capacitive conductor section 6 are interconnected outside of the slit 10.

The plane conductor section of the first embodiment has a pattern area that is much wider than ordinary wiring patterns. For example, in the passive element part 12 shown in FIG. 2, the capacitive conductor section 6 which is a plane conductor section must preferably be as wide as possible to get a capacitance (C) which is great enough.

FIG. 3 is a schematic circuit diagram of the electronic device of FIG. 2 in which an inductor (L) and a capacitor (C) are connected in parallel.

In accordance with the passive element part 12 of the first embodiment, the capacitive conductor section 6 which is a plane conductor section has a slit 10. This slit can shut off a flow of an eddy current that flows from the coil pattern 3 to the capacitive conductor section 6 and suppress an eddy current loss.

This can also suppress reduction of the Q factor (quality factor) and the inductance (L) of the inductive conductor section 4. As the result, this can suppress deterioration of the damping characteristic of the resonance circuit due to the reduction of the Q factor of the inductor (L) and actualize a resonance circuit of a high damping characteristic.

As the result, the electric characteristic of the passive element part 12 (electronic device) can be improved.

Further, reduction of the inductance (L) can be suppressed. This can suppress excess lamination of coil patterns 3 and prevent the multi-layer substrate unit 2 from becoming thick. As the result, the passive element part 12 can be downsized.

As the slit 10 of the capacitive conductor section 6 is cross-shaped with its center aligned to the center of the coil pattern 3 of the inductive conductor section 4, the slit 10 can steadily shut off a flow of eddy current that generates on the capacitive conductor section 6. This can fully suppress the eddy current loss.

This can positively suppress the reduction of the Q factor (quality factory) of the inductive conductor section 4.

The shape of the slit 10 formed on the capacitive conductor section 6 is not limited to a cross. It can be any as long as it is so formed to shut off a flow of eddy current that generates on the capacitive conductor section 6. Therefore, it is preferable that the slit has a plurality of arms radiating from a point corresponding to the center of the coil pattern 3.

Next will be explained the dimensions of dielectric substrates that constitute the passive element part 12 and conductor sections formed thereon.

As for the primary dielectric substrate 1a of FIG. 4, the conductor of the inductive conductor section 4, for example, is approximately 0.1 mm wide (A). The inductor is approximately 0.4 mm long (B) and 0.7 mm wide (J). As for the secondary dielectric substrate 1b of FIG. 5, the slit 10 of the capacitive conductor section 6 is approximately 0.1 mm (D). The condenser is 0.6 mm long (E) and 0.9 mm wide (F).

The inductive conductor sections 4 and the capacitive conductor section 6 of the above dimensions are laminated into a multi-layer substrate unit 2 of the passive element part 12 of FIG. 2.

As shown in the vertical section of the multi-layer substrate unit 2 of FIG. 6, the multi-layer substrate unit, the conductor, and the insulator are respectively about 0.32 mm (G), 0.014 mm (H), and 0.05 mm (I) in thickness. The inductive conductor section 4 and the capacitive conductor section 6 are printed with silver paste and baked at low temperatures. The inductive conductor sections 4 and the capacitive conductor sections 6 are electrically interconnected by means of through-hole wirings 8 and further connected to external connection terminals 9 by means of connection electrodes 7 as shown in FIG. 2.

To increase the Q factor (quality factor) and improve the damping characteristic of the resonance circuit provided by the passive element part 12 of the first embodiment, it is preferable to increase the thickness H (see FIG. 7) and width (A) (see FIG. 8) of the conductor. This works to reduce the parasitic resistance of the inductive conductor section 4 and consequently increases the Q factor.

FIG. 7 is a graph showing a relationship between Q factor and frequency of conductor sections on dielectric substrates of the electronic device of FIG. 7 in terms of thicknesses Hi to H3 (H1>H2>H3) of the conductor section as a parameter. The Q factors become smaller in the order of H1, H2, and H3 (that is, greatest for H1 and smallest for H3) in the preset frequency range. Therefore, the conductor should preferably be thicker.

FIG. 8 is a graph showing a relationship between Q factor and frequency of conductor sections on dielectric substrates in terms of widths Al to A3 (A1>A2>A3) of the conductor section as a parameter. The Q factors become smaller in the order of A1, A2, and A3 (that is, greatest for Al and smallest for A3) in the preset frequency range. Therefore, the conductor should preferably be wider.

Next will be explained an electronic device which is a variation of the first embodiment.

In the passive element part 12 of FIG. 9 which is a variation of the first embodiment, the plane conductor section is a GND conductor section 11 which is at a ground potential;

The passive element part 12 of FIG. 9 which is a variation of the first embodiment contains a GND conductor section 11 and inductive conductor sections 4 of coil patterns in a multi-layer substrate unit 2 which is made by lamination of three primary dielectric substrates 1a and one secondary dielectric substrate 1b. The inductive conductor sections 4 and the GND conductor section 11 are laminated vertically. Each inductive conductor section 4 has a connection electrode 7 to be connected to the external connection terminal 9.

The GND conductor section 11 contains a cross-shaped slit 10 with its center aligned to the center of the coil pattern 3 of the inductive conductor section 4.

As the slit 10 is provided in the GND conductor section 11, the slit 10 can shut off the flow of an eddy current that generates on the GND conductor section 11. This can suppress the eddy current loss.

As the result, this can suppress reduction of the Q factor (quality factor) of the inductive conductor section 4 and the inductance (L). Therefore, this can suppress deterioration of the damping characteristic of the resonance circuit due to the reduction of the Q factor of the inductor (L) and actualize a resonances circuit of a high damping characteristic.

This can also improve the electric characteristic of the variation of the passive element part 12 of FIG. 9.

To fully reinforce GND (grounding) of the variation of the passive element part 12 of FIG. 9, the GND conductor section which is the plane conductor section should preferably be as wide as possible.

Next will be explained the shapes of the slit 10 in the plane conductor section (FIG. 10 to FIG. 15) of the passive element part 12 (electronic device).

FIG. 10, FIG. 11, and FIG. 12 respectively show cross-shaped slits 10 in rectangular plane conductor sections with their longer arms parallel to the longer sides of the plane conductor sections and their shorter arms parallel to the shorter arms. The areas of the plane conductor section are interconnected outside of the slit 10 in FIG. 10, in the center of the slit 10 in FIG. 11, and completely separated from each other in FIG. 12.

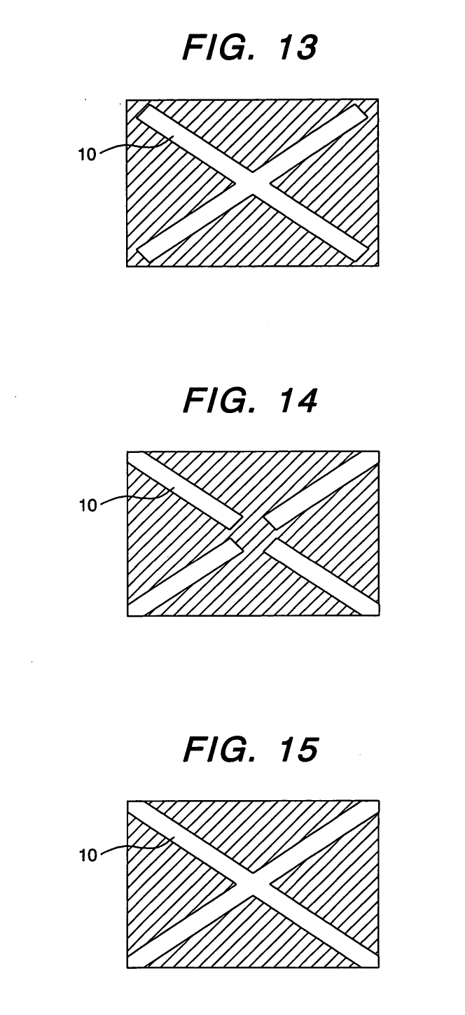

FIG. 13, FIG. 14, and FIG. 15 respectively. show approximate cross-shaped slits 10 in rectangular plane conductor sections with their arms on the diagonal lines of the rectangular plane conductor section. The areas of the plane conductor section are interconnected outside of the slit 10 in FIG. 13, in the center of the slit 10 in FIG. 14, and completely separated from each other in FIG. 15.

When a passive element part 12 contains the capacitive conductor sections 6 of FIG. 2 that have any of the slit shapes of FIG. 10 to FIG. 15, areas of the capacitive conductor section 6 on a single dielectric substrate must be connected somewhere. Therefore, slit shapes of FIG. 10, FIG. 11, FIG. 13, or FIG. 14 are preferable. However, when the conductor areas are interconnected inside the slit 10 as shown in FIG. 11 and FIG. 14, an eddy current may flow from the coil pattern 3 into this connecting area and cannot be fully. shut off.

Therefore, when containing the capacitive conductor sections 6 of FIG. 2, the passive element part 12 should preferably employ either of the slit shapes of FIG. 10 and FIG. 13 which does not place the connecting conductor area in an area where an eddy current generates (that is an area of the coil pattern 3).

When containing a GND conductor section 11 of FIG. 9, the passive element part 12 should preferably employ a slit shape that completely separates the GND conductor section 11 which is a plane conductor section in an area corresponding to the coil pattern 3. Therefore, the passive element part 12 should preferably employ either of the slit shapes of FIG. 12 and FIG. 15. Also when a slit shape of FIG. 12 or FIG. 15 is employed as the GND conductor section 11, all separated areas of the plane conductor section must be at an identical ground potential. Therefore, the separated areas must be electrically connected each other in an area outside the slit fully apart from an area corresponding to the coil pattern 3.

(Embodiment 2)

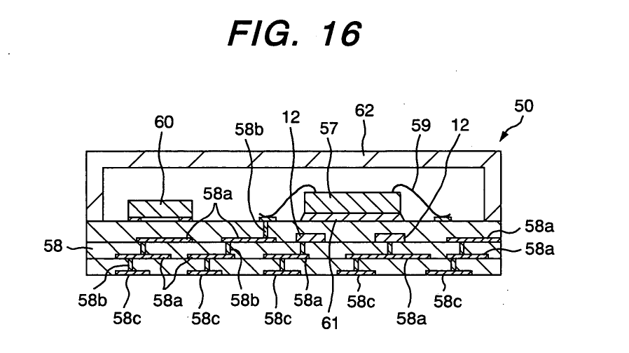

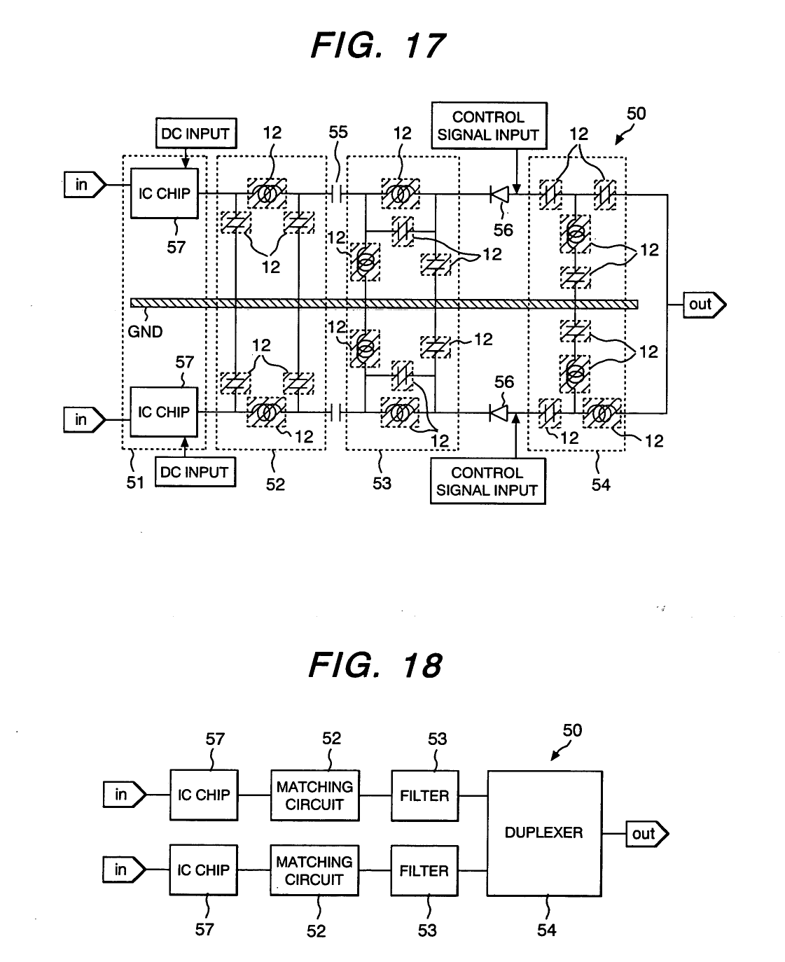

FIG. 16 is a cross-sectional view of a sample structure of a semiconductor device which is a second embodiment of this invention. FIG. 17 is a schematic circuit diagram showing an example of circuit connection of a semiconductor device of FIG. 16. FIG. 18 is a circuit block diagram showing an example of circuit configuration of a semiconductor device of FIG. 16.

The second embodiment is a semiconductor device having the passive element part 12 (that is an electronic device) of Embodiment 1. Below will be explained a high-frequency module 50 of FIG. 16 as an example of such a semiconductor.

The high-frequency module 50 consists of passive element parts 12 each of which is an electronic device of Embodiment 1,

an integrated circuit (IC) chip 57 which is a semiconductor chip containing a semiconductor element,

a chip part 60 which is a passive elements such as a capacitor or a resistor,

a multi-layer wiring board 58 which electrically connects the passive element parts 12, the IC chip 57, and the chip part 60, plural wires 59 such as gold wires which connect electrodes of the IC chips 57 to the associated terminals of the multi-layer wiring board 58,

a cap 62 for sealing the parts which are mounted on the multi-layer wiring board 58, and

lands 58c which are external terminals on the back side of the multi-layer wiring board 58.

The passive element part 12 contains coil patterns 3 and plane conductor sections as already explained by Embodiment 1. The description below assumes that the plane conductor section of FIG. 2 is a capacitive conductor section 6.

In other words, the passive element part 12 consists of

a plurality of primary dielectric substrates 1a which respectively have a circular inductive conductor section 4 and electrically connect these multi-layered circular inductive conductor sections and

a secondary dielectric substrate 1b which is laminated with said primary dielectric substrate and has a capacitive conductor section 6 on it; wherein

the capacitive conductor section 6 is laminated with a coil pattern 3 formed by lamination of the inductive conductor sections 4 and contains a slit 10.

In the high-frequency module 50 of FIG. 16, the passive element part 12 is provided on a layer in the multi-layer wiring board 58 and electrically connected to the lands 58c by means of internal wirings 58a and through-hole wirings 58b. The IC chip 57 and the chip parts 60 on the main surface of the multi-layer wiring board 58 are also connected electrically to the lands 58c by means of internal wirings 58a and through-hole wirings 58b.

Here, the passive element part 12 can be mounted on the main surface of the multi-layer wiring board 58.

Further, the high-frequency module 50 contains a plurality of IC chips 57 such as control chips and output chips. These IC chips 57 are fixed to the multi-layer wiring board 58 by means of die-bond materials 61 such as silver paste and insulating adhesives. Furthermore, the chip parts 60 are soldered to the multi-layer wiring board 58.

Here, the external terminals of the high-frequency module 50 are not limited to lands 58c. They can be,. for example, solder balls attached to the lands 58c. Further, the sealing of the high-frequency module 50 is not limited to a hermetic sealing using the cap 62. It can be a plastic sealing using a packaging resin.

Next will be explained the circuit configuration of the high-frequency module 50 which is the second embodiment of this invention.

FIG. 17 shows a circuit connection of the high-frequency module 50. FIG. 18 shows the functional block diagram of the circuit. As shown in FIG. 18, the circuit of the high-frequency module 50 consists of IC chips 57, matching circuits 52, filters 53, a duplexer 54 and so on. The matching circuits 52, filters 53, and duplexer 54 are made of a plurality of elements on the board such as capacitor elements and passive element parts 12 (hatched parts in FIG. 17) which are electronic devise.

In other words, the matching circuits 52, filters 53, and duplexer 54 are made of a plurality of passive element parts 12 and interconnected for example by capacitor elements 55, diode elements 56, and so on.

As the high-frequency module 50 of Embodiment 2 contains passive element parts 12 (electronic. devices) each of which has a slit 10 in each plane conductor section as explained by Embodiment 1, its electric characteristics can be improved. For example, when the passive element part 12 works as a filter, its damping characteristic can be improved. Generally, Q factors (quality factor) of passive element parts 12 can be increased.

Further as the passive element parts 12 can be downsized, they can be built inside the multi-layer wiring board 58 and will not make the high-frequency module 50 (semiconductor device) greater even when the passive element parts 12 are placed on the main surface of the multi-layer wiring board 58 to say nothing of when the passive element parts 12 are built in the multi-layer wiring board 58.

We inventors have described the present invention in detail in accordance with its preferred embodiments. It is to be explicitly understood, however, that the preferred embodiments are not intended as a definition of the limits of the invention and that various changes in form and details may be made therein without departing from the spirit and scope of the invention.

For example, Embodiment 1 employs a cross-shaped slit 10, but circular or rectangular slit 10 can be used. In this case, the resulting semiconductor device such as a high-frequency module 50 can have high inductor (L) and Q factor (quality factor) values.

1. An electronic device made of multi-layered dielectric substrates comprising
a plurality of primary dielectric substrates which respectively have a circular inductive conductor section and electrically connect these multi-layered circular inductive conductor sections and
a secondary dielectric substrate which is laminated with said primary dielectric substrate and has a plane conductor section on it; wherein
the laminated inductive conductor sections form a coil pattern whose ends are connected to external connection terminals.
said coil pattern is laminated with said plane conductor section, and
said plane conductor section has a slit.

2. The electronic device of claim 1, wherein said plane conductor section is at a ground potential.

3. The electronic device of claim 2, wherein said slit is cross-shaped with its center put in the center of said coil pattern.

4. The electronic device of claim 2, wherein said slit is shaped to radiate outwards with its center put in the center of said coil pattern.

5. An electronic device containing inductive conductor sections of coil patterns in a multi-layered substrate comprising a plurality of dielectric substrates and capacitive conductor sections of capacitance patterns; wherein
external connection terminals are provided to connect said inductive conductor section and said capacitive conductor sections electrically at both ends of the terminals by means of through-holes,
the capacitive conductor section of said capacitance pattern contains a slit, and
said inductive conductor sections and said capacitive conductor sections are laminated in a body.

6. The electronic device of claim 5, wherein said slit is cross-shaped with its center put in the center of said coil pattern.

7. The electronic device of claim 5, wherein said slit is cross-shaped and areas of said capacitive conductor section are interconnected in the center or outside of said slit.

8. The electronic device of claim 5, wherein said slit is cross-shaped diagonally on said capacitive conductor section.

9. The electronic device of claim 5, wherein said slit is shaped to radiate outwards with its center put in the center of said coil pattern.

10. A semiconductor device comprising
an electronic device which consists of a plurality of primary dielectric substrates which respectively have a circular inductive conductor section and electrically connect these multi-layered circular inductive conductor sections and a secondary dielectric substrate which is laminated with said primary dielectric substrate and has a plane conductor section on it, wherein said plane conductor section is laminated with the coil pattern formed by the laminated inductive conductor sections and said plane conductor section contains a slit,
a semiconductor chip which forms a semiconductor element,
a wiring substrate which electrically connects said electronic device and said semiconductor chip, and
a plurality of external terminals provided on said wiring substrate.

11. The electronic device of claim 10, wherein said plane conductor section is a capacitive conductor section having a capacitance pattern and said slit is formed on said capacitance pattern.

12. The electronic device of claim 10, wherein said slit is cross-shaped with its center put in the center of said coil pattern.

13. The electronic device of claim 10, wherein said plane conductor section is a capacitive conductor section having a capacitance pattern, said slit is cross-shaped, and areas of said capacitive conductor sections are interconnected in the center or outside of said slit.

14. The electronic device of claim 10, wherein said slit is shaped to radiate outwards with its center put in the center of said coil pattern.

15. The electronic device of claim 10, wherein said wiring substrate is a multi-layer wiring substrate and said electronic device is built in said multi-layer wiring substrate.

16. The electronic device of claim 10, wherein said plane conductor section is at a ground potential.
